(19) United States
(12) Patent Application Publication
(10) Pub. No.: US 2006/0005109 A1
(43) Pub. Date: Jan. 5, 2006

(54) Method and system for correcting errors in electronic memory devices

(75) Inventors: Alessia Marelli, Dalmine (BG) (IT); Roberto Ravasio, Ponte San Pietro (BG) (IT); Rino Micheloni, Turate (CO) (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (MI) (IT)

(21) Appl. No.: 11/169,497

(22) Filed: Jun. 29, 2005

(30) Foreign Application Priority Data
Jun. 30, 2004 (EP) 04425485.2

(51) Int. Cl. H03M 13/00

(52) U.S. Cl. 714/777

(57) ABSTRACT

A method and system for correcting errors in multilevel memories is based upon using a combination of a BCH correction code and a Hamming correction code. The BCH correction code is used for correcting multiple errors, and the Hamming correction code is used for correcting single errors. The Hamming correction code reduces the use of the decoding blocks for the BCH correction codes, which are computationally intensive.

### FIELD OF THE INVENTION

The present invention relates to a method and system for correcting errors in electronic memory devices including non-volatile memories, particularly Flash memories.

The invention particularly relates to read and write memories having a NAND structure, and the following description is made with reference to this specific field of application for convenience of illustration only, since the invention can be also applied to memories with a NOR structure provided they are equipped with an error correction system.

Even more particularly, the invention relates to a method and system for correcting errors in electronic read and write non-volatile memory devices, particularly Flash memories, of the type providing the use of a BCH (Bose-Chaudhuri-Hocquenghem) binary correction code.

### BACKGROUND OF THE INVENTION

Two-level and multilevel NAND memories have a bit error rate (BER) that requires an error correction system (ECC) to allow them to be reliably used as much as possible. Among the many known error correction systems a particular importance is assumed by the so-called cyclical correction codes, particularly BCH binary codes.

The main features of the BCH binary code are provided below by way of comparison. This code operates on a block of binary symbols. If N (4096+128) is the block size, the number of parity bits is P (52 bits). The canonical coding and decoding structures process the data block using sequential operations on the bits to be coded or decoded. The arithmetic operators (sum, multiplication, inversion) in GF(2) are extremely simple (XOR, AND, NOT). The code corrects K bits.

The structure of the error correction systems using a BCH code will now be analyzed. The typical structure of a BCH code is shown in FIG. 1, wherein the block indicated with C represents the coding step while the other BLOCKS 1, 2 and 3 are active during the decoding. They refer to the syndrome calculation, to the error detection polynomial calculation (for example, the Berlekamp algorithm) and to the error detection, respectively. BLOCK M indicates a storage and/or a transfer medium of the coded data.

BLOCKS C, 1 and 3 are formed using known sequential structures (for example, as described by Shu Lin and Daniel Costello in “Error Control Coding: Fundamentals and Applications”) and have a latency proportional to the length of the message to be stored.

In particular, for a traditional sequential implementation: BLOCK C is the block latency and is equal to the message to be stored (4096 bits); BLOCK 1 is the block latency and is equal to the coded message (for a four-error-corrector code 4096+52); and BLOCK 3 is the block latency and is equal to the coded message (for a four-error-corrector code 4096+52).

Using traditional implementations of the coding BLOCK C and syndrome calculation BLOCK 1, the latency time used for these operations can be partially or totally overlapped with respect to the information writing time in the memory and to the data reading time (without any correction) by the user. These coding and decoding steps do not require an increase in the time required for reading and writing.

At the end of the information block reading (N bits), BLOCK 1 has calculated the syndromes. If all the syndromes are equal to 0, it is not necessary to perform other operations. If the syndromes are not equal to 0, the decoding steps 2 and 3 are to be performed. The impact on the system performances given by the performance of these two steps (2 and 3), regardless of how they are implemented, is much higher the more the packages with one or more errors are frequent. Although advantageous under several aspects, known systems do not allow the frequency of use of decoding BLOCKS 2 and 3 to be reduced, while also reducing the decoding complexity.

### SUMMARY OF THE INVENTION

An object of the present invention is to provide an error correction method and system in which the burden of the decoding step is reduced, thus overcoming the drawbacks of the prior art approaches.

This and other objects, advantages and features in accordance with the present invention are provided by decreasing the frequency of use of decoding BLOCKS 2 and 3 by using the binary properties of BCH correction codes, particularly with respect to the syndromes.

It is thus possible to optimize the system speed by recognizing when a single error occurred, and by using for this case a Hamming decoding.

On the basis of this solution idea, the technical problem is solved by a system as previously indicated and defined in claim 1.

The problem is also solved by a method as previously indicated and defined in claim 4.

### BRIEF DESCRIPTION OF THE DRAWINGS

The features and advantages of the system and method according to the invention will be apparent from the following description of an embodiment thereof, given by way of a non-limiting example with reference to the attached drawings. In these drawings:

FIG. 1 is a schematic block view of a BCH coding and decoding system according to the prior art;

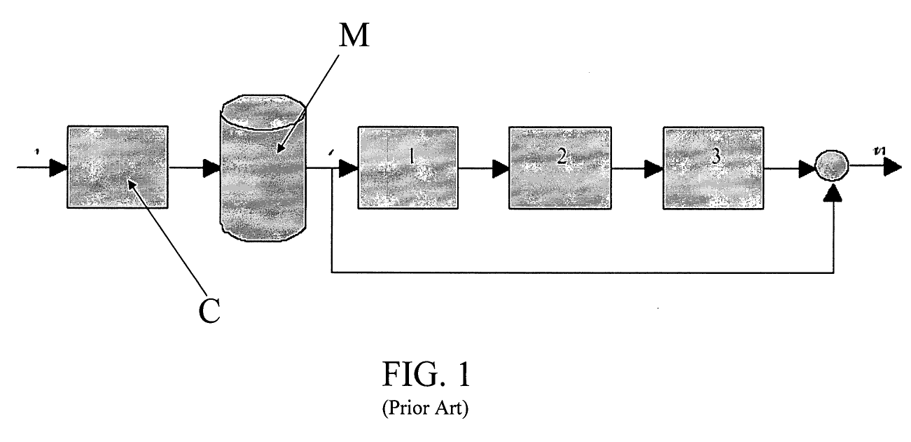

FIG. 2 is a schematic block view of a BCH coding and decoding system according to the present invention, with emphasis being placed on the error correction;

FIG. 3 is a graph illustrating a comparison between the error probabilities in two-level memories and in multilevel memories according to the present invention;

FIG. 4 is a schematic block view of a coding and decoding system according to the present invention; and

FIG. 5 is a graph illustrating a comparison between the error probabilities in two-level memories and in multilevel memories according to the present invention by indicating the frequency of use of the heaviest decoding blocks.

### DETAILED DESCRIPTION OF THE PREFERRED EMBODIMENTS

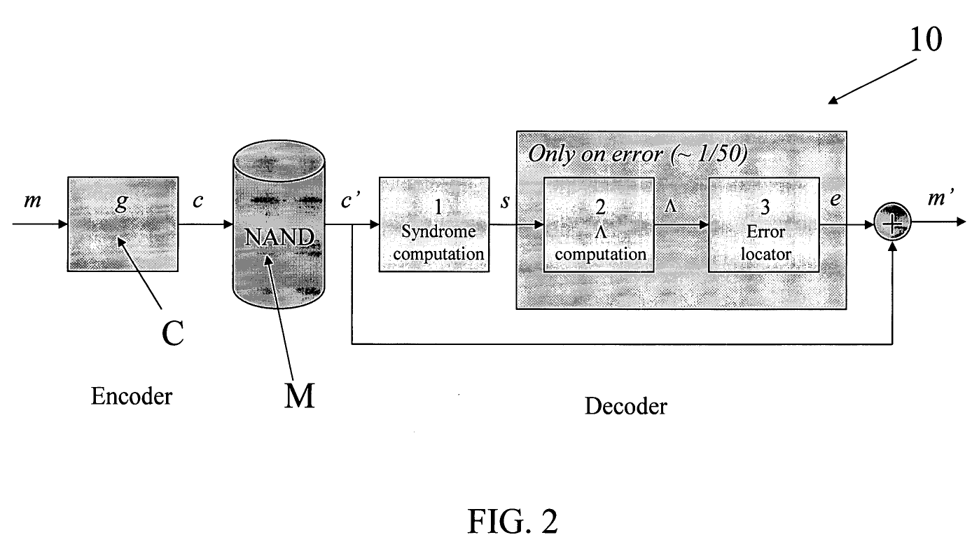

With reference to the figures, and particularly to the example of FIG. 2, an error correction system for electronic non-volatile memory devices, particularly multilevel reading and writing memories, is indicated with reference numeral 10.

The error correction system 10 comprises a block indicated with C representing the coding step, a BLOCK M indicating the electronic memory device, and a group of BLOCKS 1, 2 and 3 that are active during the decoding step. In particular, BLOCK 1 is responsible for calculating the so-called code syndrome, BLOCK 2 is a calculation block of the error detector polynomial, and BLOCK 3 is responsible for detecting the error using the Chien wrong position search algorithm.

The BCH decoding requires the syndrome calculation in BLOCK 1. This calculation can occur while the user reads data from the memory, and therefore it cannot involve a time over-head.

If all the calculated syndromes are equal to zero, the data package being read is correct or the number of errors is higher than 2K, where K indicates the code corrective capacity. If not all of the syndromes are null, it is necessary to proceed with the decoding steps 2 and 3. These steps, however implemented, involve a time over-head for the implementation thereof. The impact of this over-head on the system performance is much higher than the highest frequency at which the errors occurs.

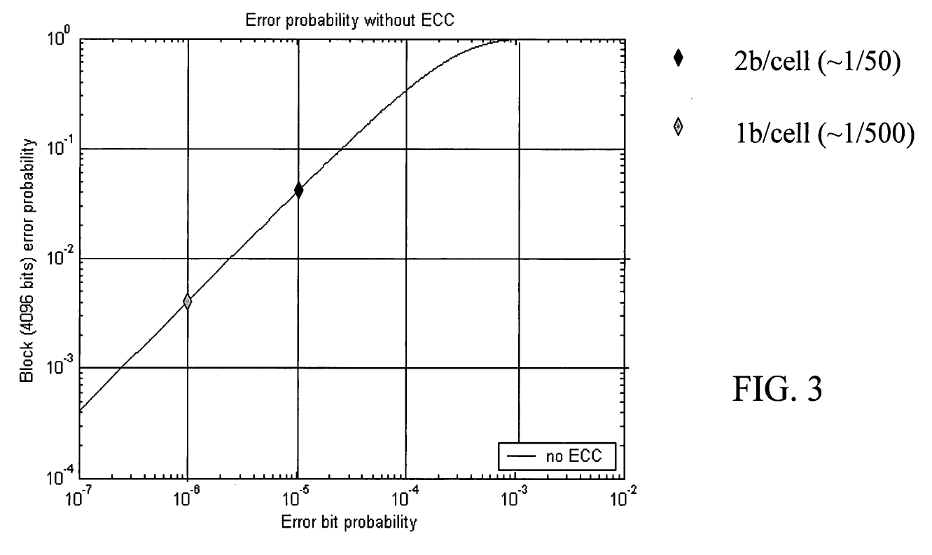

FIG. 3 emphasizes, by way of example, the error probabilities of a block of 4096 bits for EEPROM Flash memories comprising 1 bit/cell and 2 bits/cell according to the single bit error probability. The frequency at which BLOCKS 2 and 3 are to intervene in the case of multilevel memories is 1 out of 50.

The invention is particularly suitable for use in Flash EEPROM memories having a NAND structure. Nevertheless, nothing prevents the invention from being also applied to memories with a NOR structure or to other types of memories provided they are equipped with an error correction system.

Advantageously, the system is based on a combination between a BCH code and a Hamming code to obtain a decoding step with a reduced use of decoding BLOCKS 2 and 3. The mathematical basics wherein the BCH and Hamming combination is based will be described below. The final system structure will be shown afterwards.

Hamming codes are, in particular, BCH codes capable of correcting a single error. Both codes operate on a binary alphabet for which S₂ᵢ=Sᵢ². To reduce the decoding over-head due to the implementation of steps 2 and 3, a relation between the wrong message syndromes has been searched to recognize when a single error occurred, and apply in this case, a Hamming decoding.

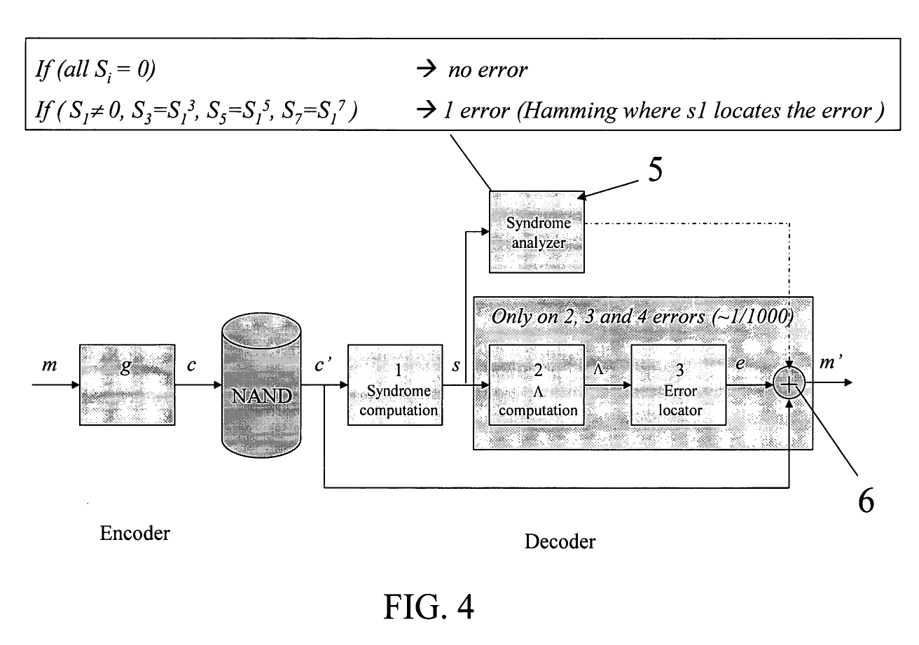

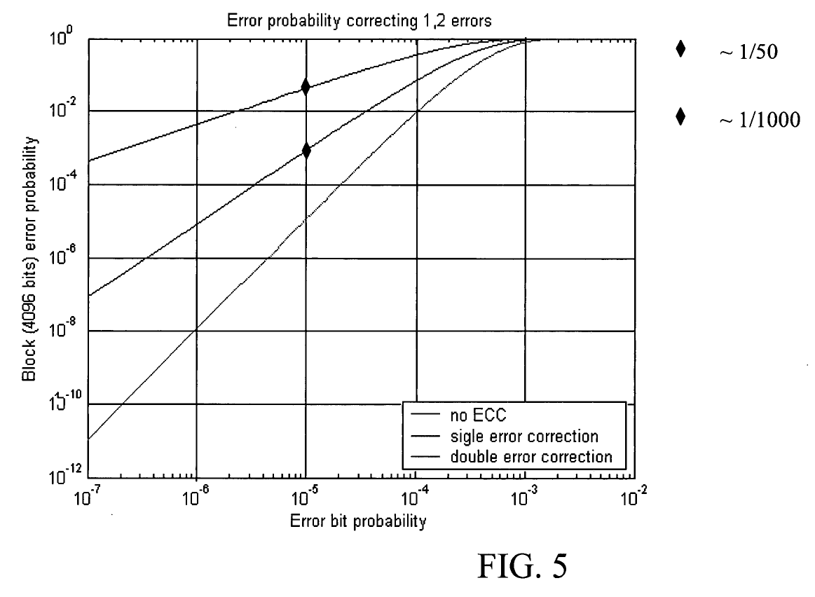

In substance, the embodiment being shown in FIG. 4 provides a preventive control step for correcting a single error and a subsequent intervention demand of the system portion implementing the Hamming decoding in BLOCK 5 in FIG. 4. Therefore, the correction frequency using BLOCKS 2 and 3 of the structure 10 drastically decreases. As exemplified in FIG. 5 in the case of 2 bits/cell Flash memories, an intervention frequency of BLOCKS 2 and 3 being equal to 1 out of 50 turns into an intervention frequency of BLOCKS 2 and 3 being equal to 1 out of 1000.

Advantageously, the preventive control step is entrusted to the so-called decoding method “syndromes”, i.e., to BLOCK 1. The syndromes immediately provide the information if an error has occurred or not.

A matrix relation is now drawn, allowing recognition from the syndromes calculated from the BLOCK 1 if a single error occurred:

$$[ \begin{matrix}{S}_{1} & {S}_{2} & {S}_{3} & ⋯ & {S}_{v} \\ {S}_{2} & {S}_{3} & {S}_{4} & ⋯ & {S}_{v + 1} \\ {S}_{3} & {S}_{4} & ⋯ & ⋯ & {S}_{v + 2} \\ ⋮ & ⋮ & ⋮ & & ⋮ \\ {S}_{v} & {S}_{v + 1} & {S}_{v + 2} & ⋯ & {S}_{2 v - 1}\end{matrix} ]$$

In this case all the matrix determinants are to be cancelled by setting v=t, v=t−1, . . . , v=2 (t indicates the code correction capacity). Only S₁ is to be different from zero. The following relations are thus obtained, also by exploiting the binary property S₂ᵢ=Sᵢ²:

$$\{ \begin{matrix}{S}_{1} \neq 0 \\ {S}_{3} = {S}_{1}^{3} \\ ⋯ \\ {S}_{2 t - 1} = {S}_{1}^{2 t - 1}\end{matrix}$$

It is worth noting that in the case of a single error, a Hamming code is used. This means that the syndrome S1 by itself identifies the wrong position.

In fact, the primitive element power corresponding to the obtained syndrome S1 represents the wrong position. If the obtained syndrome is the binary expression of the element α¹², for example, then the twelfth position is the wrong one.

BLOCK 5 of FIG. 4 identifies the relations between the above-mentioned syndromes, and if they are met, obtains from the syndrome S1 the error position. The corresponding circuitry can be specific for correcting a single error to rapidly play the role thereof.

A particular exemplifying case is represented by a combinatory logic identifying the relations between the syndromes and a ROM memory translating the syndromes into the corresponding error positions.

The situation can be summed up by saying that all the possible syndromes have an associated error configuration, and according to the present invention, a BCH correction (BLOCK 2 and 3) is used only when two or more errors occurred. The general system structure is shown in FIG. 4, and it clearly shows the presence of an analysis BLOCK 5 connected to the output of BLOCK 1 responsible for the syndrome calculation step.

The output of the BLOCK 5 is directly transferred into an adder node 6, wherein also the output of the error detection BLOCK 3 converges. Therefore, when the system 10 detects the presence of a single error, the control is entrusted to a Hamming code decoding correcting only that error.

The frequency of use of BLOCKS 2 and 3 is considerably reduced. Consequently, the speed increases since BLOCKS 2 and 3, being structurally more complex, are used rarely with respect to known approaches.

Referring to the diagram of FIG. 5, wherefrom it can be recognized how the error probability is different for single errors and for multiple errors, making use of the method and system according to the present invention is very advantageous.

The method according to the invention thus provides an alternative use of the Hamming correction code at each detection of a single error to be corrected. The detection of a single error is obtained by analyzing the result of the code syndrome calculation step at the output of BLOCK 1. Upon detecting a single error, BLOCKS 2 and 3 are bypassed and the decoding is performed only by the Hamming code.

1-8. (canceled)

9. A method for correcting errors in an electronic memory device comprising:
determining if a single error or multiple errors has occurred;
correcting the multiple errors using a BCH binary error correction code; and
correcting the single error using a Hamming correction code.

10. A method according to claim 9, further comprising performing a syndrome calculation for determining if the single error has occurred.

11. A method according to claim 10, wherein the syndrome calculation is based upon the following matrix:
$$[ \begin{matrix}{S}_{1} & {S}_{2} & {S}_{3} & ⋯ & {S}_{v} \\ {S}_{2} & {S}_{3} & {S}_{4} & ⋯ & {S}_{v + 1} \\ {S}_{3} & {S}_{4} & ⋯ & ⋯ & {S}_{v + 2} \\ ⋮ & ⋮ & ⋮ & & ⋮ \\ {S}_{v} & {S}_{v + 1} & {S}_{v + 2} & ⋯ & {S}_{2 v - 1}\end{matrix} ]$$
wherein all of the matrix determinants that are obtained are set equal to zero by setting v=2, . . . , t, and t indicates a code correction capacity and only S₁ is different from zero.

12. A method according to claim 11, further comprising using the binary property S₂ᵢ=Sᵢ² in the matrix to obtain the following relation:
$$\{ \begin{matrix}{S}_{1} \neq 0 \\ {S}_{3} = {S}_{1}^{3} \\ ⋯ \\ {S}_{2 t - 1} = {S}_{1}^{2 t - 1}\end{matrix}$$

13. A system for correcting errors in an electronic memory device comprising:
a coding block comprising a BCH binary correction code;
a cascade of decoding blocks connected to said coding block and comprising
a code syndrome block for calculating a code syndrome,
a computational block for calculating an error detector polynomial, and
an error detection block for detecting an error; and
an analysis and detection block connected to an output of said code syndrome block for detecting a single error by analyzing the code syndrome.

14. A system according to claim 13, further comprising an adder having a first input connected to an output of said analysis and detection block, and a second input connected to an output of said error detection block for reducing a decoding time for detecting the single error.

15. A system according to claim 13, wherein the output of said analysis and detection block bypasses said computational block and said error detection block.

16. A system according to claim 13, wherein the electronic memory device comprises a multilevel memory.

17. An electronic system comprising:
a memory; and
a system for correcting errors in said memory and comprising
a coding block comprising a BCH binary correction code,
a code syndrome block connected to said coding block for calculating a code syndrome,
a computational block connected to said coding block for calculating an error detector polynomial,
an error detection block connected to said computational block for detecting an error, and
an analysis and detection block connected to said code syndrome block for detecting a single error by analyzing the code syndrome.

18. An electronic system according to claim 17, further comprising an adder having a first input connected to an output of said analysis and detection block, and a second input connected to an output of said error detection block for reducing a decoding time for detecting a single error.

19. An electronic system according to claim 17, wherein the output of said analysis and detection block bypasses said computational block and said error detection block.

20. An electronic system according to claim 17, wherein said memory comprises a multilevel memory.

21. An electronic system according to claim 17, wherein said memory comprises a non-volatile memory.
